(19) United States
(12) Patent Application Publication
(10) Pub. No.: US 2007/0138599 A1
(43) Pub. Date: Jun. 21, 2007

(54) SEMICONDUCTOR DEVICE HAVING A SINGLE SIDEWALL FIN FIELD EFFECT TRANSISTOR AND METHOD FOR FABRICATING THE SAME

(75) Inventors: Young-Joon AHN, Gyeonggi-do (KR); Choong-Ho LEE, Gyeonggi-do (KR); Chul LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/465,055

(22) Filed: Aug. 16, 2006

(30) Foreign Application Priority Data
Dec. 20, 2005 (KR) 10-2005-0126362

(51) Int. Cl. H01L 29/76; H01L 29/06

(52) U.S. Cl. 257/618; 257/288

(57) ABSTRACT

A semiconductor device includes a substrate, a first fin disposed on the substrate and having first and second sidewalls opposite to each other, an isolation layer surrounding the sidewalls of the first fin, and a first gate pattern crossing the first fin, extending into the isolation layer, and covering the first sidewall of the first fin. A top surface of the isolation layer adjacent the second sidewall is located substantially at or above the level of a top surface the first fin.

### CROSS-REFERENCE TO RELATED APPLICATION

This application claims priority from Korean Patent Application No. 2005-0126362, filed Dec. 20, 2005, the disclosure of which is hereby incorporated herein by reference in its entirety.

### BACKGROUND

1. Technical Field

This disclosure relates to a semiconductor device and method for fabricating the same, and more particularly, to a semiconductor device having a single sidewall fin field effect transistor (FinFET) and method for fabricating the same.

2. Description of the Related Art

In response to the need for high-density integration of semiconductor devices, much research has been conducted for a FinFET. The FinFET includes a silicon fin protruding from a substrate, and an insulated gate pattern covering both sidewall surfaces and the top surface of the silicon fin. Source/drain regions are disposed in the silicon fin on both sides of the gate pattern. Thus, a channel region of the FinFET is formed on both sidewall surfaces and the upper surface. As a result, the FinFET has a relatively larger effective channel width as compared to a planar transistor occupying the same area. Thus, the FinFET has a structure favorable to high-density integration.

A memory device such as DRAM has a cell region including multiple fins and gate patterns.

FIGS. 1 and 2 are cross-sectional views illustrating a semiconductor device having a conventional FinFET. In FIGS. 1 and 2, section I is a cross-sectional view taken across the word line of a conventional semiconductor device, and section II is a cross-sectional view taken along the word line.

Referring to FIG. 1, an isolation layer 15 defines multiple fins 13 having a two-dimensional row and column arrangement in a semiconductor substrate 11. Gate patterns 19, 20 and 21 are disposed in parallel to cross the fins 13. Hard mask patterns 23 are disposed on the gate patterns 19, 20 and 21. A gate dielectric layer 17 is interposed between the gate patterns 19, 20 and 21 and the fins 13.

The first gate pattern 19 is disposed to cross a first fin 13 selected from the fins 13. The second gate pattern 20 is parallel to the first gate pattern 19, and disposed to cross a second fin 13 selected from the fins 13, thus extending between the first fin 13 and the third fin 13. The second fin 13 is offset from the plane of cross section I and is thus not shown in FIG. 1 cross section I. However, as can be seen in the cross section II, the first gate pattern 19 is disposed to cross other fins 13. Similarly, the second gate pattern 20 crosses the second fin 13. The third gate pattern 21 is parallel to the second gate pattern 20 and disposed to be opposite to the first gate pattern 19 and to cross the third fin 13.

As shown in cross section II, the first gate pattern 19 is disposed to cover a top surface and two opposite sidewall surfaces of the first fin 13. Furthermore, the first gate pattern 19 extends to cover a top surface and two other opposite sidewall surfaces of adjacent fins 13. A bottom surface of each of the gate patterns 19, 20 and 21 is located lower than the top surface of each of the fins 13. Thus, as shown for the second gate pattern 20 between the first and third fins 13, the bottom surface of the second gate pattern 20 is lower than the top surface of each fin 13. Similarly, the bottom surface of the first gate pattern 19 extends below the top surfaces of fins 13, thus covering two other opposite sidewalls of adjacent fins 13.

Furthermore, the second gate pattern 20 should be insulated from the first and third fins 13. To this end, the second gate pattern 20 is insulated from the fins 13 by the isolation layer 15 and the gate dielectric layer 17. However, due to increasing density of the high-density integration of semiconductor devices, a separation between the fins 13 is reduced. The reduction of the separation between the fins 13 increases the potential for electrical interference between the second gate pattern 20 and the fins 13.

In addition, structures of the gate patterns 19, 20 and 21 are very sensitive to misalignment. Referring to FIG. 2, a process of fabricating the semiconductor device includes a patterning process such as photolithography and etching processes. The patterning process may have an alignment error. Thus, the gate patterns 19, 20 and 21 and the hard mask patterns 23 can give rise to misalignment in the direction of an arrow 25. That is, misaligned gate patterns 19′, 20′ and 21′ and misaligned hard mask patterns 23′ are formed on the semiconductor substrate 11. In this case, the misaligned second gate pattern 20′ is brought into contact with one sidewall of the fin 13, thereby providing a path B of current leakage.

In another method of fabricating a semiconductor device having a FinFET, a semiconductor substrate is formed with fin active regions and an isolation layer surrounding the fin active regions. Gate patterns are formed to cross the fin active regions. At this time, the gate patterns cover sidewalls of the fin active regions.

In another method of fabricating a semiconductor device having a FinFET, a semiconductor substrate is formed with a silicon fin. A passivation layer is formed on at least one sidewall of the silicon fin. The passivation layer is partially removed to expose a channel region of the silicon fin.

Nevertheless, there is a need for technology capable of preventing an electrical interference between the gate pattern and the fin.

### SUMMARY

An embodiment includes semiconductor device including a substrate, a first fin disposed on the substrate and having first and second sidewalls opposite to each other, an isolation layer surrounding the sidewalls of the first fin, and a first gate pattern crossing the first fin, extending into the isolation layer, and covering the first sidewall of the first fin. A top surface of the isolation layer adjacent the second sidewall is located substantially at or above the level of a top surface the first fin.

Another embodiment includes a method of fabricating a semiconductor device, the method including forming a first fin having first and second sidewalls opposite to each other on a substrate, forming an isolation layer surrounding the sidewalls of the first fin, forming a mask pattern over the isolation layer, partially removing the isolation layer using the mask pattern as a mask to form a gate trench region exposing the first sidewall, forming a gate dielectric layer on the first fin and the first sidewall exposed in the gate trench region, and forming a first gate pattern crossing the first fin, filling the gate trench region. When forming the mask pattern, the mask pattern is formed overlying an edge of the second sidewall and extending over a top surface of the first fin, and having an opening overlying an edge of the first sidewall. A portion of the mask pattern overlying the edge of the second sidewall is located opposite the edge of the first sidewall under the opening.

### BRIEF DESCRIPTION OF THE DRAWINGS

The above and other features and advantages will become more apparent by describing embodiments in detail with reference to the attached drawings in which:

FIGS. 1 and 2 are cross-sectional views illustrating a semiconductor device having a conventional FinFET;

FIG. 3 is a top plan view illustrating the cell array region of a semiconductor device having a FinFET in accordance with an embodiment;

FIGS. 4 through 7 are cross-sectional views explaining a method of fabricating a semiconductor device having a FinFET in accordance with an embodiment, where section I is a cross-sectional view taken along lines I-I′ of FIG. 3, and section II is a cross-sectional view taken along lines II-II′ of FIG. 3; and

FIG. 8 is a cross-sectional view illustrating the cell array region of a DRAM having a FinFET in accordance with another embodiment, wherein section I is a cross-sectional view taken along lines I-I′ of FIG. 3, and section II is a cross-sectional view taken along lines II-II′ of FIG. 3.

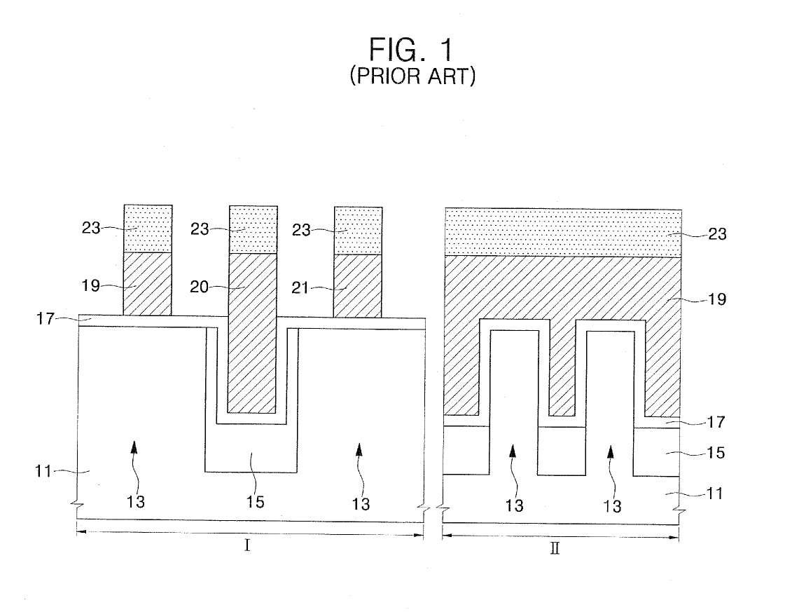

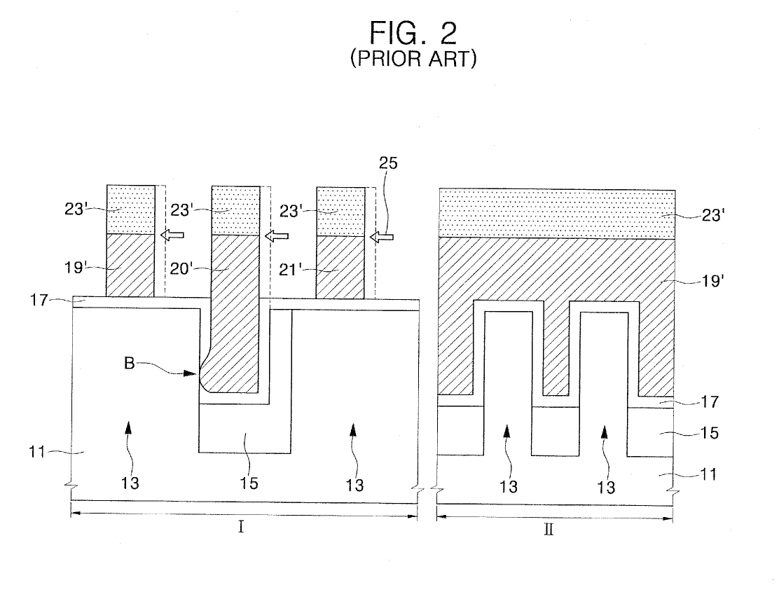

### DETAILED DESCRIPTION

Embodiments will now be described more fully hereinafter with reference to the accompanying drawings. Embodiments may, however, take many different forms and should not be construed as being limited to the embodiments set forth herein. Rather, these embodiments are provided so that this disclosure will be thorough and complete, and will fully convey the scope of the following claims to those skilled in the art. In the drawings, the thicknesses of layers and regions are exaggerated for clarity. Furthermore, when a layer is located “on” any other layer or substrate, it is directly formed on the other layer or substrate, or interposed as a third layer between them. Like numbers refer to like elements throughout the specification.

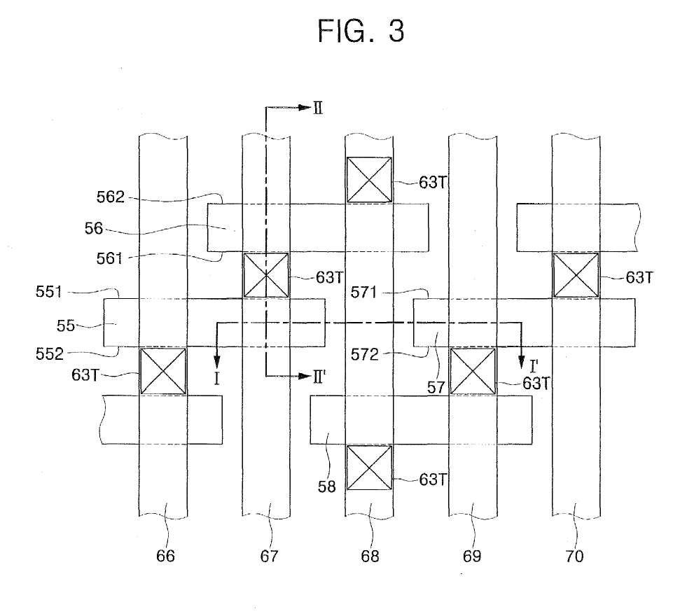

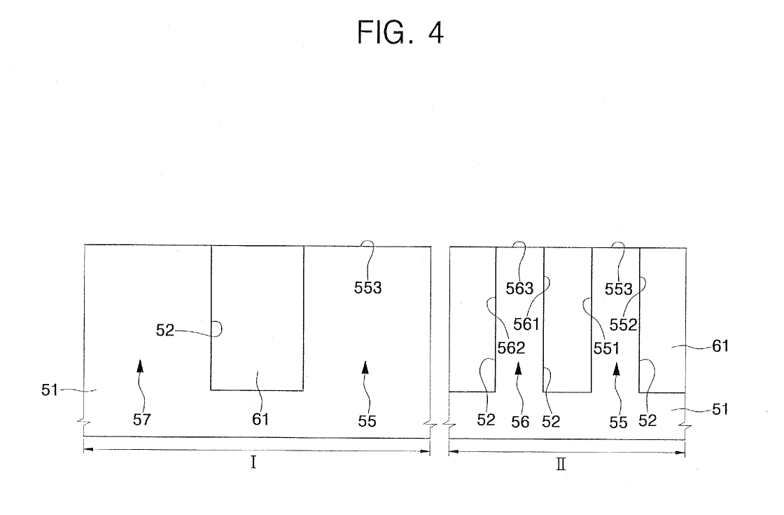

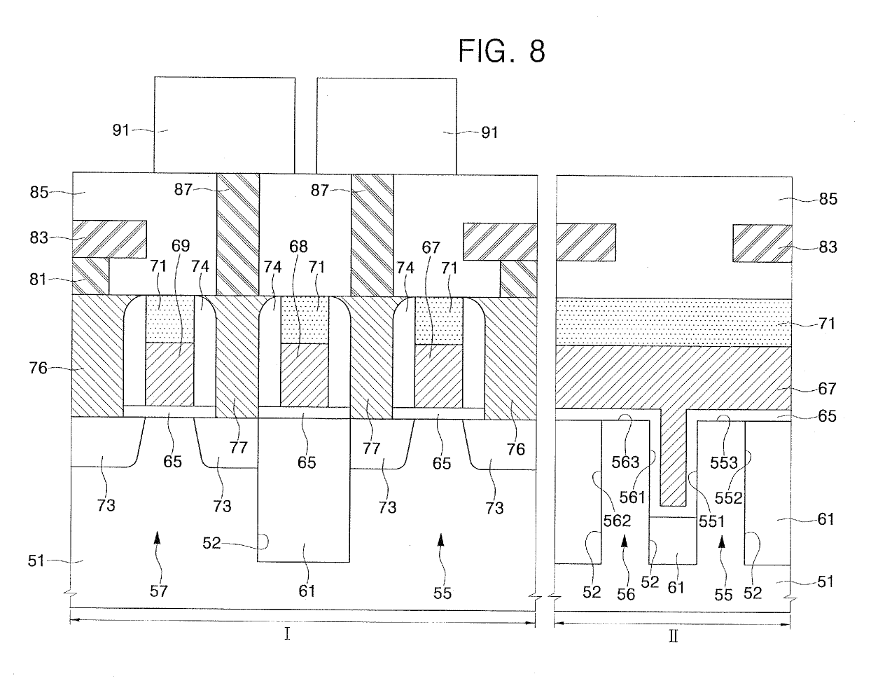

FIG. 3 is a top plan view illustrating the cell array region of a semiconductor device having a FinFET in accordance with an embodiment. FIGS. 4 through 7 are cross-sectional views explaining a method of fabricating a semiconductor device having a FinFET in accordance with an embodiment. FIG. 8 is a cross-sectional view illustrating the cell array region of a DRAM having a FinFET in accordance with another embodiment. In FIGS. 4 through 8, section I is a cross-sectional view taken along lines I-I′ of FIG. 3, and section II is a cross-sectional view taken along lines II-II′ of FIG. 3.

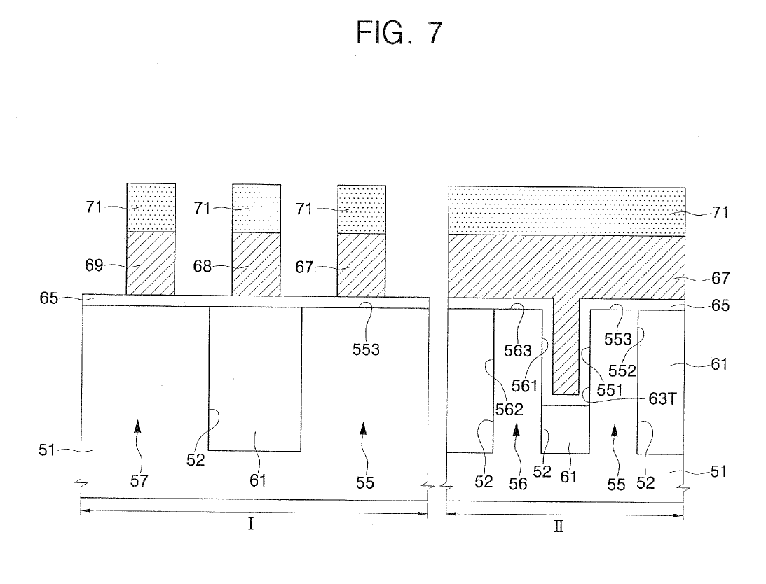

First, a semiconductor device having a FinFET according to an embodiment will be described with reference to FIGS. 3 and 7.

Referring to FIGS. 3 and 7, a substrate 51 is provided with a first fin 55 having a top surface and multiple sidewalls. The substrate 51 is a semiconductor substrate such as a silicon wafer or silicon on insulator (SOI) wafer. The substrate 51 includes multiple fins 55, 56, 57 and 58 that are two-dimensionally arranged in row and column directions. For example, the first pin 55 is disposed in parallel with respect to the second fin 56, and in series with respect to the third fin 57. The fins 55, 56, 57 and 58 are semiconductor fins formed of single crystal silicon. Furthermore, the fins 55, 56, 57 and 58 are defined by isolation trench regions 52 formed on the substrate 51.

The fins 55, 56, 57 and 58 each have a top surface and multiple sidewalls. The first fin 55 has first and second sidewalls 551 and 552 that are opposite to each other. Furthermore, the first fin 55 has a top surface 553. The second fin 56, also, has both opposite third and fourth sidewalls 561 and 562, and a top surface 563. Similarly, the third fin 57 has both opposite fifth and sixth sidewalls 571 and 572, and a top surface 573 as well. The first sidewall 551 of the first fin 55 is disposed to be opposite to the third sidewall 561 of the second fin 56. The first sidewall 551 of the first fin 55 is disposed in a row with respect to the fifth sidewall 571 of the third fin 57, and the second sidewall 552 of the first fin 55 is disposed in a row with respect to the sixth sidewall 572 of the third fin 57.

The substrate 51 is provided with an isolation layer 61. The isolation layer 61 is disposed to expose the top surfaces 553 and 563 of the fins 55, 56, 57 and 58. The isolation layer 61 is disposed to fill the isolation trench region 52. Furthermore, the isolation layer 61 has gate trench regions 63T, which expose the sidewalls of the facing fins. The top surfaces 553 and 563 of the fins 55, 56, 57 and 58 are located at substantially the same level as a top surface of the isolation layer 61. The isolation layer 61 may include an insulating layer such as a high-density plasma (HDP) oxide layer.

Gate patterns 66, 67, 68 and 69 cross the fins 55, 56, 57 and 58. The gate patterns 66, 67, 68 and 69 are substantially parallel to each other. The gate patterns 66, 67, 68 and 69 include a conductive layer such as a polysilicon layer, a metal layer, a metal silicide layer or a combination of such layers.

The first gate pattern 67 is disposed to cross the first and second fins 55 and 56. One of the gate trench regions 63T is disposed between the first and second fins 55 and 56 and exposes at least one of the first and third sidewalls 551 and 561. Furthermore, the isolation layer 61 remains on a bottom of the gate trench region 63T. The first gate pattern 67 extends to fill an interior of the gate trench region 63T. In this case, the first gate pattern 67 partly covers at least one of the first and third sidewalls 551 and 561. The first gate pattern 67 may also cover the first sidewall 551 of the first fin 55 and the third sidewall 561 of the second fin 56. The second sidewall 552 and fourth sidewall 562 below the first gate pattern 67 are covered by the isolation layer 61.

The second gate pattern 68 is disposed so as to be parallel to the first gate pattern 67, cross the second fin 56, and extend between the first fin 55 and the third fin 57. Between the first fin 55 and the third fin 57, the top surface of the isolation layer 61 is located at substantially the same level as the top surface of the first fin 55 as well as the top surface of the third fin 57, and the second gate pattern 68 is disposed on the isolation layer 61. In addition, the top surface of the isolation layer 61 between the first fin 55 and the third fin 57 may be higher than the top surface of each of the fins 55, 56, 57 and 58. Thus, between the first fin 55 and the third fin 57, the second gate pattern 68 is located at a higher level than the first and third fins 55 and 57. The fourth sidewall 562 below the second gate pattern 68 is exposed by another gate trench region 63T. In this case, the second gate pattern 68 extends so as to cover the fourth sidewall 562. The third sidewall 561 below the second gate pattern 68 is covered by the isolation layer 61.

The third gate pattern 69 is disposed so as to be parallel to the second gate pattern 68, be located opposite to the first gate pattern 67, and cross the third fin 57. The sixth sidewall 572 below the third gate pattern 69 is exposed by another gate trench region 63T. In this case, the third gate pattern 69 extends so as to cover the sixth sidewall 572 of the third fin 57. The fifth sidewall 571 below the third gate pattern 69 is covered by the isolation layer 61.

The fourth gate pattern 66 is disposed so as to be parallel to the first gate pattern 67, be located on the opposite side of the first gate pattern 67 as the second gate pattern 68, and cross the first fin 55. The second sidewall 552 below the fourth gate pattern 66 is exposed by another gate trench region 63T. In this case, the fourth gate pattern 66 extends so as to cover the second sidewall 552 of the first fin 55. The first sidewall 551 below the fourth gate pattern 66 is covered by the isolation layer 61.

The gate patterns 66, 67, 68, 69 and 70 may serve as word lines 66, 67, 68, 69 and 70, respectively. Hard mask patterns 71 are formed on the word lines 66, 67, 68, 69 and 70. Each of the hard mask patterns 71 may be a silicon nitride layer.

A gate dielectric layer 65 is interposed between the fins 55, 56, 57 and 58 and the gate patterns 66, 67, 68, 69 and 70. The gate dielectric layer 65 may be a silicon oxide layer or high-k dielectric layer. The high-k dielectric layer 65 is disposed so as to contact the top surfaces of the fins 55, 56, 57 and 58. Furthermore, the gate dielectric layer 65 is disposed so as to conformably cover inner walls of each gate trench region 63T. In other words, the gate dielectric layer 65 comes into contact with the first sidewall 551 of the first fin 55 and the third sidewall 561 of the second fin 56. The gate dielectric layer 65 comes into contact with the sixth sidewall 572 of the third fin 57. The gate dielectric layer 65 is interposed between the isolation layer 61 and the second gate pattern 68.

As stated above, the first gate pattern 67 covers the first sidewall 551 of the first fin 55 and the third sidewall 561 of the second fin 56. The first gate pattern 67 is disposed so as to cross the top surface 553 of the first fin 55. Thus, a single sidewall FinFET is formed from the first sidewall 551 and the top surface 553 of the first fin 55. The area between the first sidewall 551 of the first fin 55 and the first gate pattern 67 may be adjusted to obtain a desired electrical property. Similarly, a single sidewall FinFET is formed from the third sidewall 561 and top surface 563 of the second fin 56. These single sidewall FinFETs have a structure favorable to high-density integration, as compared to the conventional planar transistor.

Furthermore, the second sidewall 552 of the first fin 55 and the fourth sidewall 562 of the second fin 56 are fully covered by the isolation layer 61. In other words, the gate patterns 66, 67, 68, 69 and 70 cover one of the sidewalls of one selected from the fins 55, 56, 57 and 58, cross the top surfaces of the fins 55, 56, 57 and 58, and extend over the isolation layer 61. The second gate pattern 68 is disposed so as to extend between the first fin 55 and the third fin 57. The isolation layer 61 is disposed so as to fully fill the isolation trench region 52 between the first fin 55 and the third fin 57. The isolation layer 61 has the top surface located at a level substantially at or higher than the first and third fins 55 and 57. Thus, the second gate pattern 68 may be located at a higher level that the first and third fins 55 and 57.

As a result, the second gate pattern 68 has an excellent alignment margin over the conventional gate pattern. The second gate pattern 68 has a structure in which it does not come into contact with the sidewalls of the first fin 55 or third fin 57. Furthermore, the second gate pattern 68 is insulated from the sidewalls of the first and third fins 55 and 57 by the isolation layer 61. As a result, the electrical interference between the second gate pattern 68 and the first or third fin 55 or 57 is reduced.

Now, the cell array region of a DRAM having a FinFET according to another embodiment will be described with reference to FIGS. 3 and 8. Referring to FIGS. 3 and 8, a substrate 51 is provided with fins 55, 56, 57 and 58, an isolation layer 61, a gate dielectric layer 65, gate patterns 66, 67, 68, 69 and 70 and hard mask patterns 71, all of which have the same structure as described with reference to FIG. 7.

The gate patterns 66, 67, 68, 69 and 70 and the hard mask patterns 71, which are stacked in that order, have sidewalls, on each of which a dielectric spacer 74 is disposed. The dielectric spacer 74 may include a silicon oxide layer, a silicon nitride layer, a silicon oxynitride layer, or a combination of such layers. Source/drain regions 73 are provided in the fins 55, 56, 57 and 58 on both sides of the gate patterns 66, 67, 68, 69 and 70. The source/drain regions 73 may include a region with a high concentration of impurities.

Landing pads 76 and 77 are disposed on the source/drain regions 73. The landing pads 76 and 77 may be divided into bit line landing pads 76 and storage landing pads 77. The landing pads 76 and 77 may include a conductive layer such as a polysilicon layer, a metal layer, a metal silicide layer, or a combination of such layers. The landing pads 76 and 77 are electrically connected with the source/drain regions 73.

An interlayer insulating layer 85 is provided on the substrate 51 having the landing pads 76 and 77 and hard mask patterns 71. The interlayer insulating layer 85 may include a silicon oxide layer, a silicon nitride layer, a silicon oxynitride layer, or a combination of such layers. Bit lines 83 and bit line plugs 81 are disposed in the interlayer insulating layer 85. One side of each bit line plug 81 is brought into contact with each bit line landing pad 76, while the other side of each bit line plug 81 is brought into contact with each bit line 83. The bit line plugs 81 and bit lines 83 include a conductive layer such as a polysilicon layer, a metal layer, a metal silicide layer, or a combination of such layers. Each bit line 83 is electrically connected to one of the source/drain regions 73 through a bit line plug 81 and a bit line landing pad 76.

Storage nodes 91 are disposed on the interlayer insulating layer 85. Conductive plugs 87 passing through the interlayer insulating layer 85 are disposed between the storage nodes and the storage landing pads 77. One side of each conductive plug 87 contacts a storage landing pad 77, while another side of each conductive plug 87 contacts a storage node 91. The conductive plugs 87 include a conductive layer such as a polysilicon layer, a metal layer, a metal silicide layer, or a combination of such layers. Each storage node 91 is electrically connected to one of the source/drain regions 73 through a conductive plug 87 and a storage landing pad 77.

As set forth above, the single sidewall FinFET is provided on the first sidewall 551 and top surface 553 of the first fin 55. A structure of the single sidewall FinFET is more favorable for high-density integration, as compared with the conventional planar transistor. The second gate pattern 68 is located at a level higher than the first and third fins 55 and 57. Thus, it is possible to minimize electrical interference that is caused between the second gate pattern 68 and the first or third fin 55 or 57. Consequently, it is possible to realize the DRAM cell array region which has the structure favorable to the high-density integration and is capable of minimizing the electrical interference between the gate patterns 66, 67, 68, 69 and 70 and the fins 55, 56, 57 and 58.

Now, a method of fabricating a semiconductor device having a FinFET in accordance with an embodiment will be described with reference to FIGS. 3 through 7. Referring to FIGS. 3 and 4, fins 55, 56, 57 and 58 are formed on a substrate 51. The substrate 51 may be a semiconductor substrate such as a silicon wafer or SOI wafer. The substrate 51 is formed with the fins 55, 56, 57 and 58 two-dimensionally arranged in row and column directions.

Specifically, a trench mask (not illustrated) is formed on a predetermined region of the substrate 51. The trench mask may be formed of a material layer having an etch selectivity with respect to the substrate 51. For example, the trench mask may be formed of a nitride layer such as a silicon nitride layer. The substrate 51 is etched using the trench mask as an etch mask, and thereby an isolation trench region 52 defining the fins 55, 56, 57 and 58 is formed. The substrate 51 may be etched using an anisotropic etching process. The fins 55, 56, 57 and 58 are formed so as to have first and second opposite sidewalls and a top surface. As illustrated, the first fin 55 is formed in parallel with respect to the second fin 56, and in series with respect to the third fin 57. The fins 55, 56, 57 and 58 may be formed of a semiconductor fin of single crystal silicon.

The fins 55, 56, 57 and 58 are each formed so as to have a top surface and multiple sidewalls. The first fin 55 is formed so as to have first and second sidewalls 551 and 552 that are opposite to each other. Furthermore, the first fin 55 is formed so as to have a top surface 553. The second fin 56 is also formed so as to have both opposite third and fourth sidewalls 561 and 562, and a top surface 563. Similarly, the third fin 57 is formed so as to have both opposite fifth and sixth sidewalls 571 and 572, and a top surface 573 as well. The first sidewall 551 of the first fin 55 is formed to be opposite to the third sidewall 561 of the second fin 56. The first sidewall 551 of the first fin 55 is formed in a row with respect to the fifth sidewall 571 of the third fin 57, and the second sidewall 552 of the first fin 55 is formed in a row with respect to the sixth sidewall 572 of the third fin 57.

An insulating layer, which fills the isolation trench region 52 and covers the substrate 51, is formed. By using processes of partly removing the insulating layer and removing the trench mask, an isolation layer 61 filling the isolation trench region 52 is formed. In other words, the isolation layer 61 is formed to surround the fins 55, 56, 57 and 58. The process of partly removing the insulating layer may include a chemical mechanical polishing (CMP) process or an etch back process. In this case, the isolation layer 61 is formed so as to expose the top surfaces 553 and 563 of the fins 55, 56, 57 and 58. Furthermore, the top surfaces 553 and 563 of the fins 55, 56, 57 and 58 are formed so as to have substantially the same level as a top surface of the isolation layer 61. Alternatively, the top surface of the isolation layer 61 is formed so as to protrude with respect to the fins 55, 56, 57 and 58. The isolation layer 61 may be formed of an insulating layer such as a high-density plasma (HDP) oxide layer.

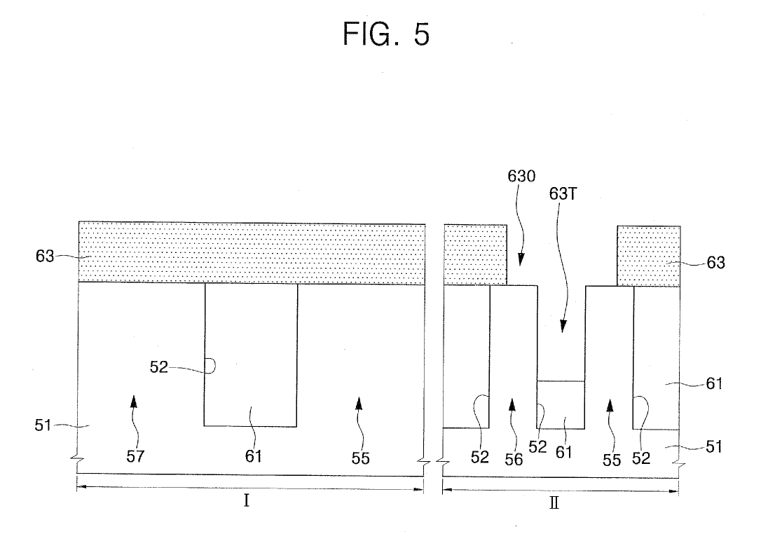

Referring to FIGS. 3 and 5, a mask pattern 63 is formed on the substrate 51 having the isolation layer 61.

The mask pattern 63 is formed of a material layer having an etch selectivity with respect to the isolation layer 61. The mask pattern 63 may be formed of a nitride layer such as a silicon nitride layer, or a photoresist layer. The mask pattern 63 is formed so as to have an opening 630 that partly exposes the isolation layer 61 between the first fin 55 and the second fin 56. Furthermore, the mask pattern 63 expands so as to partly expose the top surfaces 553 and 563 of the first and second fins 55 and 56, respectively.

The isolation layer 61 is partly removed using the mask pattern 63 as an etch mask, thereby forming a gate trench region 631. Within the gate trench region 63T, at least one of the first sidewall 551 of the first fin 55 and the third sidewall 561 of the second pin 56 is partly exposed. Furthermore, within the gate trench region 63T, the first sidewall 551 of the first fin 55 and the third sidewall 561 of the second pin 56 may be partly exposed at the same time. Then, the mask pattern 63 is removed. The process of partly removing the isolation layer 61 may be performed under conditions of having an etch selectivity with respect to the fins 55, 56, 57 and 58.

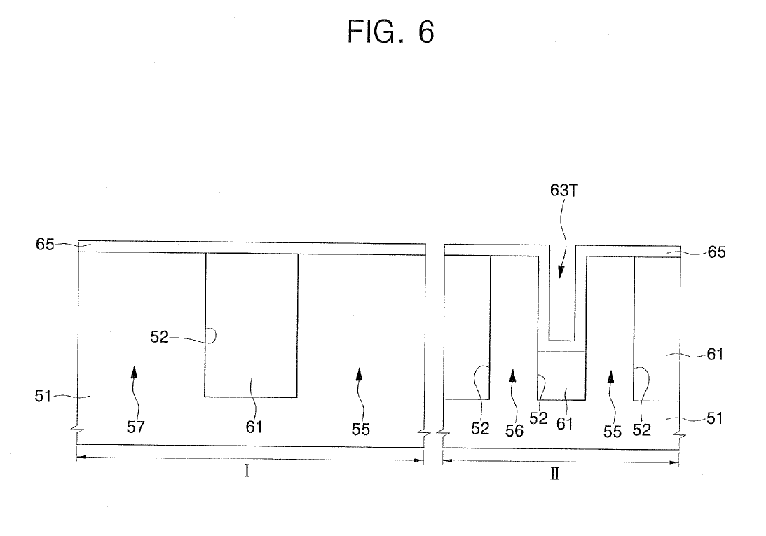

Referring to FIGS. 3 and 6, a gate dielectric layer 65 is formed on the substrate having the gate trench region 63T. The gate dielectric layer 65 may be formed of a silicon oxide layer or a high-k dielectric layer.

The gate dielectric layer 65 is formed so as to cover the top surfaces and exposed sidewalls of the fins 55, 56, 57 and 58. Furthermore, the gate dielectric layer 65 is formed so as to conformably cover inner walls of each gate trench region 63T. Thus, the gate dielectric layer 65 is formed to come into contact with the first sidewall 551 of the first fin 55 and the third sidewall 561 of the second fin 56. In addition, the gate dielectric layer 65 is formed so as to cover the top surface of the isolation layer 61.

Referring to FIGS. 3 and 7, gate patterns 66, 67, 68, 69 and 70, which are parallel to each other, are formed on the substrate 51 having the gate dielectric layer 65. Specifically, a gate conductive layer is formed on the substrate 51 having the gate dielectric layer 65. The gate conductive layer is formed so as to fill the gate trench region 63T and cover a top surface of the substrate 51. The gate conductive layer may be formed of a polysilicon layer, a metal layer, a metal silicide layer, or a combination of such layers. Hard mask patterns 71 are formed on the gate dielectric layer 65. The hard mask patterns 71 are formed of a material layer having an etch selectivity with respect to the gate conductive layer. The hard mask patterns 71 may be formed of a nitride layer such as a silicon nitride layer. The gate conductive layer is partly removed by using the hard mask patterns 71 as an etch mask, thereby forming the gate patterns 66, 67, 68, 69 and 70.

The gate patterns 66, 67, 68, 69 and 70 are formed so as to cross the fins 55, 56, 57 and 58 and be parallel to each other. As illustrated, the first gate pattern 67 is formed so as to cross the first and second fins 55 and 56 and fill the gate trench regions 63T. The second gate pattern 68 is formed so as to be parallel to the first gate pattern 67, cross the second fin 56, and extend over the isolation layer 61 between the first fin 55 and the third fin 57. The third gate pattern 69 is disposed so as to be parallel to the second gate pattern 68, be located opposite to the first gate pattern 67, and cross the third fin 57. The third gate pattern 69 is formed so as to partly cover the sixth sidewall 572 of the third fin 57. The fourth gate pattern 66 is disposed so as to be parallel to the first gate pattern 67, be located on a side of the first gate pattern 67 opposite to the second gate pattern 68, and cross the first fin 55. The fourth gate pattern 66 extends so as to cover the second sidewall 552 of the first fin 55. The first sidewall 551 below the fourth gate pattern 66 is covered by the isolation layer 61. Although the gate patterns have been described as being parallel to one another, such gate patterns may be substantially parallel as a result of the limits of semiconductor manufacturing processes.

The first gate pattern 67 is formed so as to fill the gate trench region 63T. That is, the first gate pattern 67 covers the first sidewall 551 of the first fin 55 and third sidewall 561 of the second fin 56. Between the first fin 55 and the third fin 57, the top surface of the isolation layer 61 is located at substantially the same level as the top surface 553 of the first fin 55 as well as the top surface of the third fin 57, and the second gate pattern 68 is formed on the isolation layer 61. Thus, the second gate pattern 68 is formed so as to be located at a higher level than the first and third fins 55 and 57.

Now, a method of fabricating the cell array region of a DRAM having a FinFET in accordance with another embodiment will be described with reference to FIGS. 3 through 8. Referring to FIGS. 3 and 8 again, a substrate 51 is formed with fins 55, 56, 57 and 58, an isolation layer 61, a gate dielectric layer 65, gate patterns 66, 67, 68, 69 and 70 and hard mask patterns 71, in the same method as described with reference to FIGS. 4 through 7. Source/drain regions 73 are formed in the fins 55, 56, 57 and 58 on both sides of the gate patterns 66, 67, 68, 69 and 70. The source/drain regions 73 may include a region with a high concentration of impurities. The gate patterns 66, 67, 68, 69 and 70 and the hard mask patterns 71, which are stacked in that order, have sidewalls, on each of which a dielectric spacer 74 is formed. The dielectric spacer 74 may be formed of a silicon oxide layer, a silicon nitride layer, a silicon oxynitride layer, or a combination of such layers.

Landing pads 76 and 77 are formed on the source/drain regions 73. The landing pads 76 and 77 are divided into bit line landing pads 76 and storage landing pads 77. The landing pads 76 and 77 may be formed of a polysilicon layer, a metal layer, a metal silicide layer, or a combination of such layers. The landing pads 76 and 77 are electrically connected with the source/drain regions 73.

An interlayer insulating layer 85 is formed on the substrate 51 having the landing pads 76 and 77 and hard mask patterns 71. The interlayer insulating layer 85 may be formed of a silicon oxide layer, a silicon nitride layer, a silicon oxynitride layer, or a combination of such layers. Bit lines 83 and bit line plugs 81 are formed in the interlayer insulating layer 85. One side of each bit line plug 81 is formed so as to contact a bit line landing pad 76, while the other side of each bit line plug 81 is formed so as to contact a bit line 83. The bit line plugs 81 and bit lines 83 may be formed of a polysilicon layer, a metal layer, a metal silicide layer, or a combination of such layers. Each bit line 83 is electrically connected to one selected from the source/drain regions 73 through a bit line plug 81 and a bit line landing pad 76.

Conductive plugs 87 passing through the interlayer insulating layer 85 are formed. The conductive plugs 87 are formed of a polysilicon layer, a metal layer, a metal silicide layer, or a combination of such layers. Storage nodes 91 are disposed on the interlayer insulating layer 85. Thus, the conductive plugs 87 passing through the interlayer insulating layer 85 are formed between the storage nodes and the storage landing pads 77. One side of each conductive plug 87 contacts a storage landing pad 77, while the other side of each conductive plug 87 contacts a storage node 91. Each storage node 91 is electrically connected to one of the source/drain regions 73 through a conductive plug 87 and a storage landing pad 77.

Embodiments are not limited to those described above, but can be modified in various different forms within the scope of the claims. For example, an embodiment may be applied to the cell array region of a memory device and method of fabricating the same.

According to an embodiment, the substrate may include a first fin, a second fin opposite to the first fin, and a third fin adjacent to the first fin. The first fin includes first and second sidewalls opposite to each other, and the second fin includes third and fourth sidewalls opposite to each other. An isolation layer surrounding the sidewalls of the fins is provided. A first gate pattern crossing the first and second fins is provided. The first gate pattern extends in the isolation layer between the first and second fins to cover the first and third sidewalls. Each of the first and third sidewalls may form a single sidewall FinFET. The second and fourth sidewalls below the first gate pattern may contact the isolation layer. Furthermore, a second gate pattern is provided that is parallel to the first gate pattern and crosses above the isolation layer between the first and second fins. The second gate pattern between the first and third fin may be disposed at a higher level than the first and third fins. Thus, it is possible to minimize electrical interference that is caused between the second gate pattern and the fins. In addition, it is possible to realize a semiconductor device that has a structure favorable to high-density integration and having reduced electrical interference between the gate patterns and the fins.

While embodiments have been particularly shown and described with reference to the drawings, it will be understood by those of ordinary skill in the art that various changes in form and details may be made therein without departing from the spirit and scope as defined by the following claims.

What is claimed is:

1. A semiconductor device comprising:
a substrate;
a first fin disposed on the substrate and having first and second sidewalls opposite to each other;
an isolation layer surrounding the sidewalls of the first fin; and
a first gate pattern crossing the first fin, extending into the isolation layer, and covering the first sidewall of the first fin;
wherein a top surface of the isolation layer adjacent the second sidewall and opposite the first gate pattern covering the first sidewall is located substantially at or above the level of a top surface the first fin.

2. The semiconductor device according to claim 1, further comprising a gate dielectric layer interposed between the first fin and the first gate pattern.

3. The semiconductor device according to claim 1, further comprising a second fin having third and fourth sidewalls and disposed such that the fourth sidewall faces the second sidewall;
wherein the isolation layer surrounds the sidewalls of the second fin, and the first gate pattern extends to cross the second fin and cover the third sidewall.

4. The semiconductor device according to claim 3, further comprising:
a third fin having filth and sixth sidewalls and disposed adjacent to the first fin on the substrate, wherein the isolation layer surrounds the sidewalls of the third fin; and
a second gate pattern disposed to extend above the isolation layer between the first and third fins at a level substantially at or above the top surface of the first fin and covering the fourth sidewall.

5. The semiconductor device according to claim 4, wherein the second gate pattern is substantially parallel to the first gate pattern, crosses the second fin, and covers the fourth sidewall.

6. The semiconductor device according to claim 4, further comprising a third gate pattern substantially parallel to the second gate pattern and crossing the third fin,
wherein the sixth sidewall is substantially coplanar with the second sidewall and is covered by the third gate pattern.

7. The semiconductor device according to claim 1, further comprising a fourth gate pattern substantially parallel to the first gate pattern, crossing the first fin, and covering the second sidewall.

8. The semiconductor device according to claim 1, further comprising:
a storage node disposed on the substrate;
wherein the first fin further comprises source/drain regions disposed in the fins on both sides of the first gate patterns, and the storage node is electrically coupled to one of the source/drain regions.

9. The semiconductor device according to claim 8, further comprising:
a landing pad disposed on the one of the source/drain regions; and
a conductive plug disposed on the landing pad;
wherein the storage node is electrically coupled to the one of the source/drain regions through the conductive plug and the landing pad.

10. A method of fabricating a semiconductor device, the method comprising:
forming a first fin having first and second sidewalls opposite to each other on a substrate;
forming an isolation layer surrounding the sidewalls of the first fin;
forming a mask pattern over the isolation layer, the mask pattern overlying an edge of the second sidewall and extending over a top surface of the first fin, and the mask pattern having an opening overlying an edge of the first sidewall, wherein a portion of the mask pattern overlying the edge of the second sidewall is located opposite the edge of the first sidewall under the opening;
partially removing the isolation layer using the mask pattern as a mask to form a gate trench region exposing the first sidewall;
forming a gate dielectric layer on the first fin and the first sidewall exposed in the gate trench region; and
forming a first gate pattern crossing the first fin, filling the gate trench region.

11. The method according to claim 10, further comprising:
forming a second fin having third and fourth sidewalls opposite to each other on the substrate;
wherein:
forming the mask pattern further comprises forming the mask pattern over an end of the second fin, the mask pattern having a second opening over an edge of the third sidewall and an edge of the second sidewall; and
partially removing the isolation layer further comprises partially removing the isolation layer using the mask pattern as the mask to form a second gate trench region exposing the third sidewall and the second sidewall.

12. The method according to claim 11, further comprising:
forming a third fin having fifth and sixth sidewalls, the third fin disposed such that the fifth sidewall faces the second sidewall; and
wherein forming the mask pattern further comprises forming the mask pattern over the isolation layer between the first fin, the third fin, and the end of the second fin.

13. A semiconductor device comprising:
a first gate pattern;
a first fin disposed under the first gate pattern;
a second fin disposed horizontally offset from the first gate pattern; and
an isolation layer disposed around the first fin and the second fin, the isolation layer having a first surface under the first gate pattern, the first surface located adjacent the second fin and substantially at or above a level of a top surface of the second fin.

14. The semiconductor device according to claim 13, further comprising:
a third fin disposed horizontally offset from the first gate pattern on an opposite side of the first gate pattern as the second fin;
wherein the isolation layer is disposed between the second fin and the third fin, and the first surface of the isolation layer is substantially at or above a level of a top surface of the third fin.

15. The semiconductor device according to claim 14, further comprising:
a second gate pattern disposed over the third fin and horizontally offset from the first fin;
wherein a second surface of the isolation layer is disposed under the second gate pattern, the second surface located adjacent the first fin and substantially at or above a level of a top surface of the first fin.

16. The semiconductor device according to claim 13, further comprising:
a third fin disposed under the first gate pattern;
wherein the first surface extends beneath the first gate pattern from the first fin to the third fin.

17. The semiconductor device according to claim 13, further comprising:
a second gate pattern disposed over the first fin and the second fin having a portion extending into the isolation layer between the first fin and the second fin; and
a third fin disposed horizontally offset from the second gate pattern and under the first gate pattern;
wherein a second surface of the isolation layer is disposed adjacent the third fin, under the second gate pattern, and substantially at or above a level of a top surface of the third fin.
